(19) United States
(12) Patent Application Publication
(10) Pub. No.: US 2025/0232091 A1
(43) Pub. Date: Jul. 17, 2025

(54) Large Language Model Driven Design Verifications And Reviews

(71) Applicant: Halliburton Energy Services, Inc., Houston, TX (US)

(72) Inventors: Xiaoguang Allan Zhong, Singapore (SG); Shobeir Pirayeh Gar, Carrollton, TX (US)

(73) Assignee: Halliburton Energy Services, Inc., Houston, TX (US)

(21) Appl. No.: 18/414,323

(22) Filed: Jan. 16, 2024

(51) Int. Cl. G06F 30/27

(52) U.S. Cl. CPC G06F 30/27

(57) ABSTRACT

A method for generating a compliance report that includes receiving, by a report generator, a technical plan and a compliance constraint, processing the technical plan and the compliance constraint, generating the compliance report based on the processing, and providing the compliance report to a user.

### BACKGROUND

The oil and gas industry may use wellbores as fluid conduits to access subterranean deposits of various fluids and minerals which may include hydrocarbons. A drilling operation may be utilized to construct the fluid conduits which are capable of producing hydrocarbons disposed in subterranean formations. Wellbores may be constructed, in increments, as tapered sections, which sequentially extend into a subterranean formation.

### BRIEF DESCRIPTION OF DRAWINGS

These drawings illustrate certain aspects of some examples of the present disclosure and should not be used to limit or define the disclosure.

FIG. 1 is a diagram of an example drilling environment.

FIG. 2 is a diagram of an example computing environment.

FIG. 3A is a diagram of a computing system with a report generator and various components used by the report generator.

FIG. 3B is a diagram of a training database and the data therein.

FIG. 3C is a diagram of a compliance database and the data therein.

FIG. 3D is a diagram of a compliance report.

FIG. 3E is a report generator and the components therein.

FIG. 4 is a flowchart of a method for training a report generator using a training database.

FIG. 5 is a flowchart of a method for using a report generator to generate a compliance report.

FIG. 6 is a flowchart of a method of the internal components of a report generator when generating a compliance report.

FIG. 7 is a table of an example compliance report.

### DETAILED DESCRIPTION

### Overview and Advantages

In general, this application discloses one or more embodiments of methods and systems for generating a compliance report for a technical plan of a well system. In one or more embodiments, a large language model (LLM) may be trained and utilized to review a technical plan (with dozens, hundreds, or thousands of varying documents), check the documents for errors (e.g., mistakes, inconsistencies, noncompliance, etc.), and generate a compliance report detailing those errors and proposing corrective actions. Accordingly, the design, construction, and operation of the well system receives thorough review and correction in the initial stages of the larger project.

Generally, to extract hydrocarbons (e.g., oil and gas) from subterranean formations, a well system is designed and constructed to facilitate the capture of those resources. However, prior to the construction of such a well system, a technical plan is generated that thoroughly details (nearly) every aspect of the design, construction, and utilization of the wells. Such a technical plan may include references to legal requirements, references to required standards, materials, sourcing of materials, equipment, sourcing of equipment, list of personnel, and/or any other relevant factor for the well system.

Conventionally, due to the broad scope and required detail of the technical plan—significant time, effort, and knowledge are needed to draft the various documents that comprise the technical plan. Further, as there are multiple contributors with only partially overlapping technical expertise, such a document may not be entirely reviewable by any single person involved. Accordingly, any errors in the technical plan may be difficult to identify—and even if found, may not have an obvious correction.

As an example, an attorney reviewing the technical plan may identify that some of the materials needed for construction are subject to regulatory export restrictions from the country specified to source the material. Accordingly, the specific material cannot be exported from the source to the well location. However, the attorney lacks the technical expertise to propose a correction that satisfies existing engineering constraints. In turn, an applications engineer proposes a change in material that satisfies the necessary structural requirements and legal constraints. However, the changes proposed by the application engineer cause a portion of the design to become noncompliant with an environmental standard required by the end user. Consequently, an environmental specialist proposes replacing the noncompliant components with compliant components that achieve the same function but operate differently than the noncompliant components. This proposal satisfies all of the outstanding legal and technical constraints. Consequently, due to the breadth of the proposed changes, the technical plan needs to be re-reviewed and re-approved by a government permitting agency. However, the government review requires several months and will cause an unacceptable delay for the entire project, thereby failing a time (and cost) constraint.

Continuing with the example above, after time (and cost) are spent attempting to satisfy the competing constraints, it is determined that a recently issued regulation (of which the attorney was unaware) requires the government (of the country with the controlled material) to grant a waiver of the export restriction if certain conditions are met. Further, the project specified in the technical plan satisfies those waiver requirements and therefore the waiver would be granted. Accordingly, when initially reviewing the technical plan, the attorney should have proposed modifying the document to note the applicability of the export restriction, the existence and need for a waiver, and then add the procedure for obtaining the waiver to the relevant process documentation of the technical plan. Further, it is also found that the same material (as originally proposed) is available to be sourced from another country, without export restriction, for 10% more than the cost of the original source (and still within the cost constraints). However, the procurement specialist that initially proposed the sourcing was unaware that the provider changed their country of export, and the procurement specialist was not tasked with reviewing the technical plan and proposing a solution.

Accordingly, with conventional methods, effort and time are spent iteratively correcting errors of a technical plan. Further, errors may go unnoticed until an issue arises at a later point. As an example, a technical plan may specify certain pipe diameters in some drawings that conflict with pipe diameters specified in text for a related component. In turn, pipe connections with varying diameters are ordered from different suppliers. When the incompatible parts arrive to be assembled, construction is halted until the correct parts can be obtained. Only at this late stage (during construction) the error (inconsistent pipe diameters) is finally identified in the technical plan.

As disclosed in one or more embodiments herein, a large language model (LLM) may be trained to generate a “compliance report” that may (i) identify errors in a technical plan (e.g., existence of export restriction, conflicting pipe diameters, etc.), and (ii) provide proposed corrective actions to those errors (e.g., waiver of export restrictions, order the material from a different source, correct pipe diameter). Further, during the training and utilization of the LLM, the LLM may access a compliance database that specifies all of the potentially relevant legal and technical constraints, including those applicable to the technical plan. Thus, when “reviewing” the document, the LLM may consider all constraints-as a single entity-to propose a solution that simultaneously satisfies all of the specified compliance constraints (and not constraints related to one specialty).

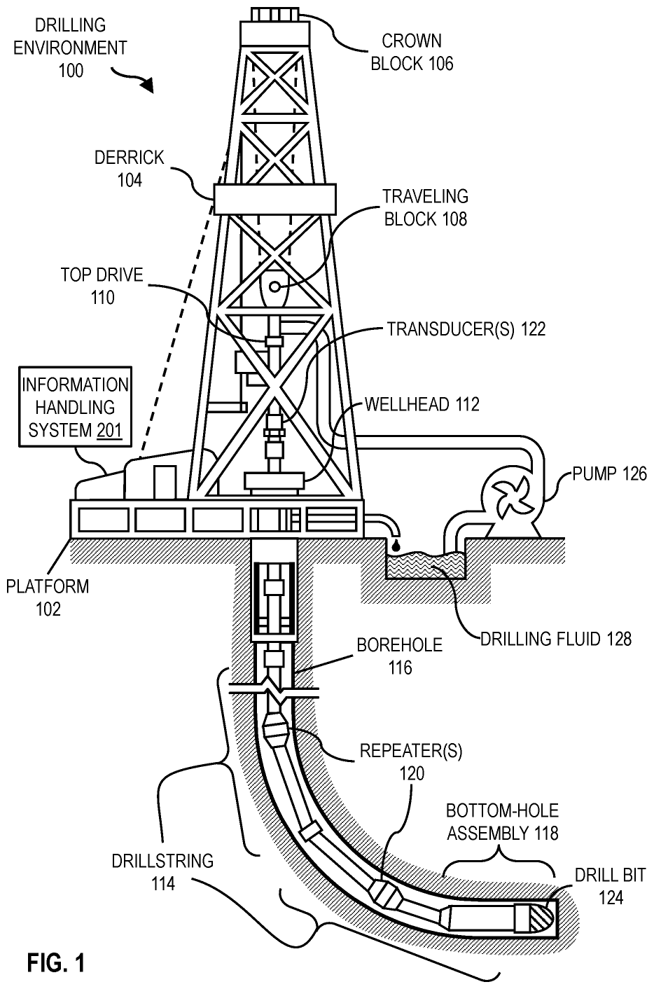

### FIG. 1

FIG. 1 is a diagram of an example drilling environment. Drilling environment 100 may include platform 102 that supports derrick 104 having a traveling block 108 for raising and lowering top drive 110 and drillstring 114. Top drive 110 supports and rotates drillstring 114 as it is lowered through wellhead 112. In turn, drill bit 124, located at the end of drillstring 114, may create borehole 116. Each of these components is described below.

Platform 102 is a structure which may be used to support one or more other components of drilling environment 100 (e.g., derrick 104). Platform 102 may be designed and constructed from suitable materials (e.g., concrete) which are able to withstand the forces applied by other components (e.g., the weight and counterforces experienced by derrick 104). In any embodiment, platform 102 may be constructed to provide a uniform surface for drilling operations in drilling environment 100.

Derrick 104 is a structure which may support, contain, and/or otherwise facilitate the operation of one or more pieces of the drilling equipment. In any embodiment, derrick 104 may provide support for crown block 106, traveling block 108, and/or any part connected to (and including) drillstring 114. Derrick 104 may be constructed from any suitable materials (e.g., steel) to provide the strength necessary to support those components.

Crown block 106 is one or more simple machine(s) which may be rigidly affixed to derrick 104 and include a set of pulleys (e.g., a “block”), threaded (e.g., “reeved”) with a drilling line (e.g., a steel cable), to provide mechanical advantage. Crown block 106 may be disposed vertically above traveling block 108, where traveling block 108 is threaded with the same drilling line.

Traveling block 108 is one or more simple machine(s) which may be movably affixed to derrick 104 and include a set of pulleys, threaded with a drilling line, to provide mechanical advantage. Traveling block 108 may be disposed vertically below crown block 106, where crown block 106 is threaded with the same drilling line. In any embodiment, traveling block 108 may be mechanically coupled to drillstring 114 (e.g., via top drive 110) and allow for drillstring 114 (and/or any component thereof) to be lifted from (and out of) borehole 116. Both crown block 106 and traveling block 108 may use a series of parallel pulleys (e.g., in a “block and tackle” arrangement) to achieve significant mechanical advantage, allowing for the drillstring to handle greater loads (compared to a configuration that uses non-parallel tension). Traveling block 108 may move vertically (e.g., up, down) within derrick 104 via the extension and retraction of the drilling line.

Top drive 110 is a machine which may be configured to rotate drillstring 114. Top drive 110 may be affixed to traveling block 108 and configured to move vertically within derrick 104 (e.g., along with traveling block 108). In any embodiment, the rotation of drillstring 114 (caused by top drive 110) may allow for drillstring 114 to carve borehole 116. Top drive 110 may use one or more motor(s) and gearing mechanism(s) to cause rotations of drillstring 114. In any embodiment, a rotatory table (not shown) and a “Kelly” drive (not shown) may be used in addition to, or instead of, top drive 110.

Wellhead 112 is a machine which may include one or more pipes, caps, and/or valves to provide pressure control for contents within borehole 116 (e.g., when fluidly connected to a well (not shown)). In any embodiment, during drilling, wellhead 112 may be equipped with a blowout preventer (not shown) to prevent the flow of higher-pressure fluids (in borehole 116) from escaping to the surface in an uncontrolled manner. Wellhead 112 may be equipped with other ports and/or sensors to monitor pressures within borehole 116 and/or otherwise facilitate drilling operations.

Drillstring 114 is a machine which may be used to carve borehole 116 and/or gather data from borehole 116 and the surrounding geology. Drillstring 114 may include one or more drillpipe(s), one or more repeater(s) 120, and bottom-hole assembly 118. Drillstring 114 may rotate (e.g., via top drive 110) to form and deepen borehole 116 (e.g., via drill bit 124) and/or via one or more motor(s) attached to drillstring 114.

Borehole 116 is a hole in the ground which may be formed by drillstring 114 (and one or more components thereof). Borehole 116 may be partially or fully lined with casing to protect the surrounding ground from the contents of borehole 116, and conversely, to protect borehole 116 from the surrounding ground.

Bottom-hole assembly 118 is a machine which may be equipped with one or more tools for creating, providing structure, and maintaining borehole 116, as well as one or more tools for measuring the surrounding environment (e.g., measurement while drilling (MWD), logging while drilling (LWD)). In any embodiment, bottom-hole assembly 118 may be disposed at (or near) the end of drillstring 114 (e.g., in the most “downhole” portion of borehole 116).

Non-limiting examples of tools that may be included in bottom-hole assembly 118 include a drill bit (e.g., drill bit 124), casing tools (e.g., a shifting tool), a plugging tool, a mud motor, a drill collar (thick-walled steel pipes that provide weight and rigidity to aid the drilling process), actuators (and pistons attached thereto), a steering system, and any measurement tool (e.g., sensors, probes, particle generators, etc.).

Further, bottom-hole assembly 118 may include a telemetry sub to maintain a communications link with the surface (e.g., with information handling system 201). Such telemetry communications may be used for (i) transferring tool measurement data from bottom-hole assembly 118 to surface receivers, and/or (ii) receiving commands (from the surface) to bottom-hole assembly 118 (e.g., for use of one or more tool(s) in bottom-hole assembly 118).

Non-limiting examples of techniques for transferring tool measurement data (to the surface) include mud pulse telemetry and through-wall acoustic signaling. For through-wall acoustic signaling, one or more repeater(s) 120 may detect, amplify, and re-transmit signals from bottom-hole assembly 118 to the surface (e.g., to information handling system 201), and conversely, from the surface (e.g., from information handling system 201) to bottom-hole assembly 118.

Repeater 120 is a device which may be used to receive and send signals from one component of drilling environment 100 to another component of drilling environment 100. As a non-limiting example, repeater 120 may be used to receive a signal from a tool on bottom-hole assembly 118 and send that signal to information handling system 201. Two or more repeaters 120 may be used together, in series, such that a signal to/from bottom-hole assembly 118 may be relayed through two or more repeaters 120 before reaching its destination.

Transducer 122 is a device which may be configured to convert non-digital data (e.g., vibrations, other analog data) into a digital form suitable for information handling system 201. As a non-limiting example, one or more transducer(s) 122 may convert signals between mechanical and electrical forms, enabling information handling system 201 to receive the signals from a telemetry sub, on bottom-hole assembly 118, and conversely, transmit a downlink signal to the telemetry sub on bottom-hole assembly 118. In any embodiment, transducer 122 may be located at the surface and/or any part of drillstring 114 (e.g., as part of bottom-hole assembly 118).

Drill bit 124 is a machine which may be used to cut through, scrape, and/or crush (i.e., break apart) materials in the ground (e.g., rocks, dirt, clay, etc.). Drill bit 124 may be disposed at the frontmost point of drillstring 114 and bottom-hole assembly 118. In any embodiment, drill bit 124 may include one or more cutting edges (e.g., hardened metal points, surfaces, blades, protrusions, etc.) to form a geometry which aids in breaking ground materials loose and further crushing that material into smaller sizes. In any embodiment, drill bit 124 may be rotated and forced into (i.e., pushed against) the ground material to cause the cutting, scraping, and crushing action. The rotations of drill bit 124 may be caused by top drive 110 and/or one or more motor(s) located on drillstring 114 (e.g., on bottom-hole assembly 118).

Pump 126 is a machine that may be used to circulate drilling fluid 128 from a reservoir, through a feed pipe, to derrick 104, to the interior of drillstring 114, out through drill bit 124 (through orifices, not shown), back upward through borehole 116 (around drillstring 114), and back into the reservoir. In any embodiment, any appropriate pump 126 may be used (e.g., centrifugal, gear, etc.) which is powered by any suitable means (e.g., electricity, combustible fuel, etc.).

Drilling fluid 128 is a liquid which may be pumped through drillstring 114 and borehole 116 to collect drill cuttings, debris, and/or other ground material from the end of borehole 116 (e.g., the volume most recently hollowed by drill bit 124). Further, drilling fluid 128 may provide conductive cooling to drill bit 124 (and/or bottom-hole assembly 118). In any embodiment, drilling fluid 128 may be circulated via pump 126 and filtered to remove unwanted debris.

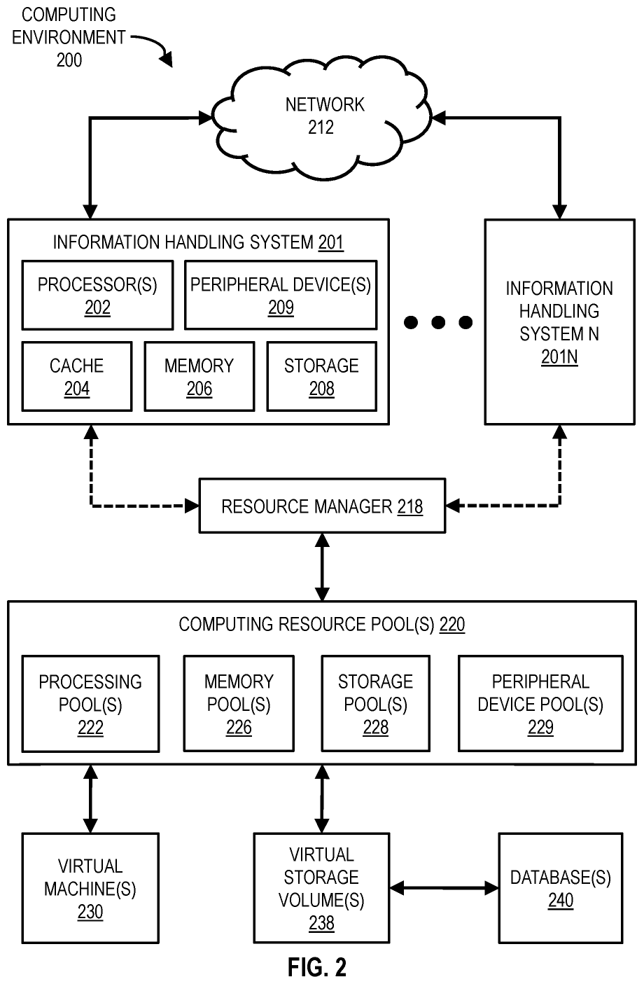

Information handling system 201 is a hardware computing system which may be operatively connected to drillstring 114 (and/or other various components of the drilling environment). In any embodiment, information handling system 201 may utilize any suitable form of wired and/or wireless communication to send and/or receive data to and/or from other components of drilling environment 100. In any embodiment, information handling system 201 may receive a digital telemetry signal, demodulate the signal, display data (e.g., via a visual output device), and/or store the data. In any embodiment, information handling system 201 may send a signal (with data) to one or more components of drilling environment 100 (e.g., to control one or more tools on bottom-hole assembly 118). Additional details regarding information handling system 201 are in the description for FIG. 2.

### FIG. 2

FIG. 2 is a diagram of an example computing environment. Computing environment 200 may include one or more information handling system(s) 201 connected via network 212. Further, resource manager 218 may aggregate and manage the allocation of the computing resources (of one or more information handling system(s) 201) into computing resource pool(s) 220. Those computing resource pool(s) 220 may then be allocated to various virtualized and/or logical components (e.g., virtual machine(s) 230, virtual storage volume(s) 238, etc.). Each of these components is described below.

Information handling system 201 is a hardware computing device which may be utilized to perform various steps, methods, and techniques disclosed herein (e.g., via the execution of software). In any embodiment, information handling system 201 may include one or more processor(s) 202, cache 204, memory 206, storage 208, and/or one or more peripheral device(s) 209. Any two or more of these components may be operatively connected via a system bus (not shown) that provides a means for transferring data between those components. Although each component is depicted and disclosed as individual functional components, these individual components may be combined (or divided) into any combination or configuration of components.

A system bus is a system of hardware connections (e.g., sockets, ports, wiring, conductive tracings on a printed circuit board (PCB), etc.) used for sending (and receiving) data to (and from) each of the components connected thereto. In any embodiment, a system bus allows for communication via an interface and protocol (e.g., inter-integrated circuit (I2C), peripheral component interconnect (express) (PCI(e)) fabric, etc.) that may be commonly recognized by the components utilizing the system bus. In any embodiment, a basic input/output system (BIOS) may be configured to transfer information between the components using the system bus (e.g., during initialization of information handling system 201).

In any embodiment, information handling system 201 may additionally include internal physical interface(s) (e.g., serial advanced technology attachment (SATA) ports, peripheral component interconnect (PCI) ports, PCI express (PCIe) ports, next generation form factor (NGFF) ports, M.2 ports, etc.) and/or external physical interface(s) (e.g., universal serial bus (USB) ports, recommended standard (RS) serial ports, audio/visual ports, etc.). Internal physical interface(s) and external physical interface(s) may facilitate the operative connection to one or more peripheral device(s) 209.

Non-limiting examples of information handling system 201 include a general-purpose computer (e.g., a personal computer, desktop, laptop, tablet, smart phone, etc.), a network device (e.g., switch, router, multi-layer switch, etc.), a server (e.g., a blade-server in a blade-server chassis, a rack server in a rack, etc.), a controller (e.g., a programmable logic controller (PLC)), and/or any other type of computing device with the aforementioned capabilities. Further, information handling system 201 may be operatively connected to another information handling system 201 via network 212 in a distributed computing environment. As used herein, a “computing device” may be equivalent to an information handling system.

Processor 202 is a hardware device which may take the form of an integrated circuit configured to process computer-executable instructions (e.g., software). Processor 202 may execute (e.g., read and process) computer-executable instructions stored in cache 204, memory 206, and/or storage 208. Processor 202 may be a self-contained computing system, including a system bus, memory, cache, and/or any other components of a computing device. Processor 202 may include multiple processors, such as a system having multiple physically separate processors in different sockets, or a system having multiple processor cores on a single physical chip. A multi-core processor may be symmetric or asymmetric. Multiple processors 202, and/or processor cores thereof, may share resources (e.g., cache 204, memory 206) or may operate using independent resources.

Non-limiting examples of processor 202 include general-purpose processor (e.g., a central processing unit (CPU)), an application specific integrated circuit (ASIC), a programmable gate array (PGA), a field programmable gate array (FPGA), a digital signal processor (DSP), and any digital or analog circuit configured to perform operations based on input data (e.g., execute program instructions).

Cache 204 is one or more hardware device(s) capable of storing digital information (e.g., data) in a non-transitory medium. Cache 204 expressly excludes transitory media (e.g., transitory waves, energy, carrier signals, electromagnetic waves, signals per se, etc.). Cache 204 may be considered “high-speed”, having comparatively faster read/write access than memory 206 and storage 208, and therefore utilized by processor 202 to process data more quickly than data stored in memory 206 or storage 208. Accordingly, processor 202 may copy needed data to cache 204 (from memory 206 and/or storage 208) for comparatively speedier access when processing that data. In any embodiment, cache 204 may be included in processor 202 (e.g., as a subcomponent). In any embodiment, cache 204 may be physically independent, but operatively connected to processor 202.

Memory 206 is one or more hardware device(s) capable of storing digital information (e.g., data) in a non-transitory medium. Memory 206 expressly excludes transitory media (e.g., transitory waves, energy, carrier signals, electromagnetic waves, signals per se, etc.). In any embodiment, when accessing memory 206, software (executed via processor 202) may be capable of reading and writing data at the smallest units of data normally accessible (e.g., “bytes”). Specifically, memory 206 may include a unique physical address for each byte stored thereon, thereby enabling the ability to access and manipulate (read and write) data by directing commands to a specific physical address associated with a byte of data (i.e., “random access”). Non-limiting examples of memory 206 devices include flash memory, random access memory (RAM), dynamic RAM (DRAM), static RAM (SRAM), resistive RAM (ReRAM), read-only memory (ROM), and electrically erasable programmable ROM (EEPROM). In any embodiment, memory 206 devices may be volatile or non-volatile.

Storage 208 is one or more hardware device(s) capable of storing digital information (e.g., data) in a non-transitory medium. Storage 208 expressly excludes transitory media (e.g., transitory waves, energy, carrier signals, electromagnetic waves, signals per se, etc.). In any embodiment, the smallest unit of data readable from storage 208 may be a “block” (instead of a “byte”). Prior to reading and/or manipulating the data on storage 208, one or more block(s) may be copied to an intermediary storage medium (e.g., cache 204, memory 206) where the data may then be accessed in “bytes” (e.g., via random access). In any embodiment, data on storage 208 may be accessed in “bytes” (like memory 206). Non-limiting examples of storage 208 include integrated circuit storage devices (e.g., a solid-state drive (SSD), Non-Volatile Memory Express (NVMe), flash memory, etc.), magnetic storage devices (e.g., a hard disk drive (HDD), floppy disk, magnetic tape, diskette, cassettes, etc.), optical media (e.g., a compact disc (CD), digital versatile disc (DVD), etc.), and printed media (e.g., barcode, quick response (QR) code, punch card, etc.).

As used herein, “non-transitory computer readable medium” is cache 204, memory 206, storage 208, and/or any other hardware device capable of non-transitorily storing and/or carrying data.

Peripheral device 209 is a hardware device configured to send (and/or receive) data to (and/or from) information handling system 201 via one or more internal and/or external physical interface(s). Any peripheral device 209 may be categorized as one or more “types” of computing devices (e.g., an “input” device, “output” device, “communication” device, etc.). However, such categories are not comprehensive and are not mutually exclusive. Such categories are listed herein strictly to provide understandable groupings of the potential types of peripheral devices 209. As such, peripheral device 209 may be an input device, an output device, a communication device, and/or any other optional computing component.

An input device is a hardware device that receives data into information handling system 201. In any embodiment, an input device may be a human interface device which facilitates user interaction by collecting data based on user inputs (e.g., a mouse, keyboard, camera, microphone, touchpad, touchscreen, fingerprint reader, joystick, gamepad, etc.). In any embodiment, an input device may collect data based on raw inputs, regardless of human interaction (e.g., any sensor, logging tool, audio/video capture card, etc.). In any embodiment, an input device may be a reader for accessing data on a non-transitory computer readable medium (e.g., a CD drive, floppy disk drive, tape drive, scanner, etc.).

An output device is a hardware device that sends data from information handling system 201. In any embodiment, an output device may be a human interface device which facilitates providing data to a user (e.g., a visual display monitor, speakers, printer, status light, haptic feedback device, etc.). In any embodiment, an output device may be a writer for facilitating storage of data on a non-transitory computer readable medium (e.g., a CD drive, floppy disk drive, magnetic tape drive, printer, etc.).

A communication device is a hardware device capable of sending and/or receiving data with one or more other communication device(s) (e.g., connected to another information handling system 201 via network 212). A communication device may communicate via any suitable form of wired interface (e.g., Ethernet, fiber optic, serial communication etc.) and/or wireless interface (e.g., Wi-Fi® (Institute of Electrical and Electronics Engineers (IEEE) 802.11), Bluetooth® (IEEE 802.15.1), etc.) and utilize one or more protocol(s) for the transmission and receipt of data (e.g., transmission control protocol (TCP), user datagram protocol (UDP), internet protocol (IP), remote direct memory access (RDMA), etc.). Non-limiting examples of a communication device include a network interface card (NIC), a modem, an Ethernet card/adapter, and a Wi-Fi® card/adapter.

An optional computing component is any hardware device that operatively connects to information handling system 201 and extends the capabilities of information handling system 201. Non-limiting examples of an optional computing components include a graphics processing unit (GPU), a data processing unit (DPU), and a docking station.

As used herein, “software” (e.g., “code”, “algorithm”, “application”, “routine”) is data in the form of computer-executable instructions. Processor 202 may execute (e.g., read and process) software to perform one or more function(s). Non-limiting examples of functions may include reading existing data, modifying existing data, generating new data, and using any capability of information handling system 201 (e.g., reading existing data from memory 206, generating new data from the existing data, sending the generated data to a GPU to be displayed on a monitor). Although software physically persists in cache 204, memory 206, and/or storage 208, one or more software instances may be depicted, in the figures, as an external component of any information handling system 201 that interacts with one or more information handling system(s) 201.

Network 212 is a collection of connected information handling systems (e.g., 201, 201N) that allows for the exchange of data and/or the sharing of computing resources therebetween. Non-limiting examples of network 212 include a local area network (LAN), a wide area network (WAN) (e.g., the Internet), a mobile network, any combination thereof, and any other type of network that allows for the communication of data and sharing of resources among computing devices operatively connected thereto. A person of ordinary skill in the relevant art, having the benefit of this detailed description, would appreciate that a network is a collection of operatively connected computing devices that enables communication between those computing devices.

As used herein, “computing resource” refers to the functional capabilities (and/or portions of functional capabilities) of any component of information handling system 201. As an example, processor 202 may have “processor resources” which may be divided into slices of processor time, any of which may be considered a “computing resource”. Cache 204, memory 206, and storage 208 may each be categorized into their own type of “computing resource”, as well as any smaller increment of storage therein (e.g., “bytes”, “blocks”). As a non-limiting example, a single memory 206 device may be divided into ranges of bytes that may be separately allocated. The storage capacity of the entire memory 206 device may be considered a “computing resource” and any subdivision (byte range) thereof may also be considered a “computing resource”. As another non-limiting example, a network interface card may have a total throughput capacity, that total throughput may be divided into portions of bandwidth. The entire throughput may be considered a “computing resource” and any smaller portion of bandwidth may also be considered a “computing resource”.

Resource manager 218 is a software instance that manages the allocation of computing resources. In any embodiment, resource manager 218 is configured (i.e., programmed) to query one or more information handling system(s) 201 to identify the computing resources available therein, and in turn, may aggregate those computing resources into one or more computing resource pool(s) 220, per the type of computing resource. Resource manager 218 may use one or more database(s) (e.g., database 240) to track the availability, allocation, and/or utilization of computing resources (e.g., as computing resource pools(s) 220). In any embodiment, resource manager 218 may create, initialize, stop, and/or terminate one or more virtual machine(s) 230, software container(s), virtual storage volume(s) 238, and/or database(s) 240. Non-limiting examples of resource manager 218 include any orchestrator, hypervisor, and/or container manager.

Computing resource pool 220 is a data structure that includes one or more pool(s) for specific types of computing resources (e.g., processing pool(s) 222, memory pool(s) 226, storage pool(s) 228, peripheral device pool(s) 229, etc.). In any embodiment, computing resource pool 220 is a data structure, created and/or managed by resource manager 218, which tracks the various computing resources of information handling systems 201 in computing environment 200. Computing resource pool(s) 220 may take the form of a table, file, and/or any other data structure capable of including information relevant to computing resources.

Processing pool 222 is a data structure that includes an aggregation of the capabilities and/or functionalities of one or more processor(s) 202 in one or more information handling system(s) 201. In any embodiment, processing pool 222, presents a unified virtual computing resource which may be allocated, by resource manager 218, to any software (e.g., virtual machine 230) and/or virtual storage volume 238.

Memory pool 226 is a data structure that includes an aggregation of the capabilities and/or functionalities of one or more memory 206 device(s) in one or more information handling system(s) 201. In any embodiment, memory pool 226, presents a unified virtual computing resource which may be allocated, by resource manager 218, to any software (e.g., virtual machine 230) and/or virtual storage volume 238.

Storage pool 228 is a data structure that includes an aggregation of the capabilities and/or functionalities of one or more storage 208 device(s) in one or more information handling system(s) 201. In any embodiment, storage pool 228, presents a unified virtual computing resource which may be allocated, by resource manager 218, to any software (e.g., virtual machine 230) and/or virtual storage volume 238.

Peripheral device pool 229 is a data structure that includes an aggregation of the capabilities and/or functionalities of one or more peripheral device(s) 209 in one or more information handling system(s) 201. In any embodiment, peripheral device pool 229, presents a unified virtual computing resource which may be allocated, by resource manager 218, to any software (e.g., virtual machine 230) and/or virtual storage volume 238.

Virtual machine 230 is a software instance which provides a virtual environment in which other software may execute. In any embodiment, virtual machine 230 may be created by resource manager 218, where resource manager 218 allocates some portion of computing resources (e.g., in one or more computing resource pool(s) 220) to virtual machine 230 to initialize and execute. In any embodiment, within virtual machine 230, the computing resources may be aggregated from one or more information handling system(s) 201 (e.g., via computing resource pool(s) 220) and presented as unified “virtual” resources within virtual machine 230 (e.g., virtual processor(s), virtual memory, virtual storage, virtual peripheral device(s), etc.). As computing resource pool(s) 220 are used to generate virtual machine 230, the underlying hardware storing, executing, and processing the operations (of virtual machine 230) may disposed in any number of information handling system(s) 201.

Virtual storage volume 238 is a virtual space for storing data. In any embodiment, virtual storage volume 238 may use any suitable means of underlying device(s) for storing data (e.g., cache 204, memory 206, storage 208) via one or more computing resource pool(s) 220. In any embodiment, virtual storage volume 238 may be managed by virtual machine 230, where virtual machine 230 handles the access (reads/writes), filesystem, redundancy, and addressability of the data stored therein.

Database 240 is a data structure that stores information in relational tuples and attributes. In any embodiment, database 240 may be stored on virtual storage volume 238 and/or directly on a single information handling system 201. Non-limiting examples of database 240 include one or more table(s) each with one or more “row(s)” (e.g., tuple(s)) and “column(s)” (e.g., attribute(s)), a structured file for storing tabular data (e.g., a comma-separated value (CSV) file, a tab-separated value (TSV) file, etc.), a relational database management system (RDBMS) (e.g., using Structured Query Language (SQL)), and/or any other data structure capable of storing data.

One of ordinary skill in the art, provided the benefit of this detailed description, would understand that computing environment 200 may not be actively operatively connected to one or more components of drilling environment 100. That is, in one or more embodiments, computing environment 200 (and any components thereof) may be located elsewhere (e.g., in a data center, office workspace, distributed in various locations, etc.). Further, any such computing environment 200 may receive data from one or more components of drilling environment 100 indirectly (e.g., accessing a database of previously recorded data, receiving data remotely over a wide area network, etc.). Drilling environment 100 and computing environment 200 are merely two examples of environments in which any data described herein may be obtained, analyzed, processed, and generated.

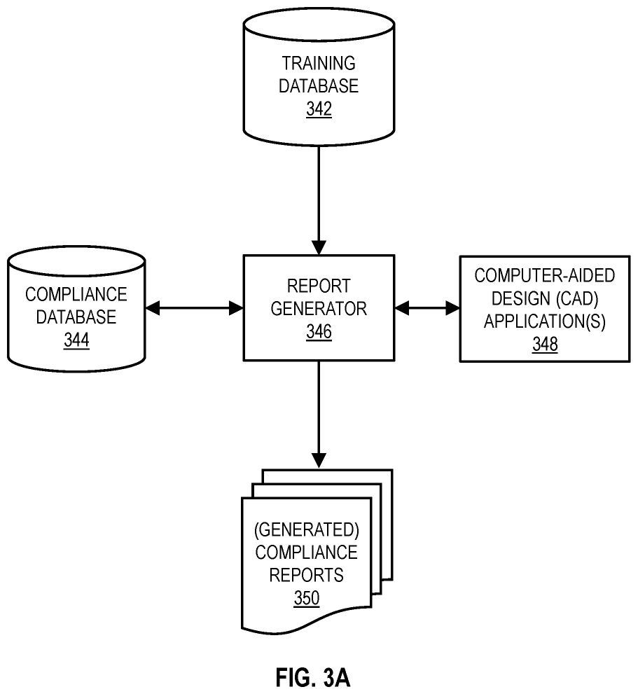

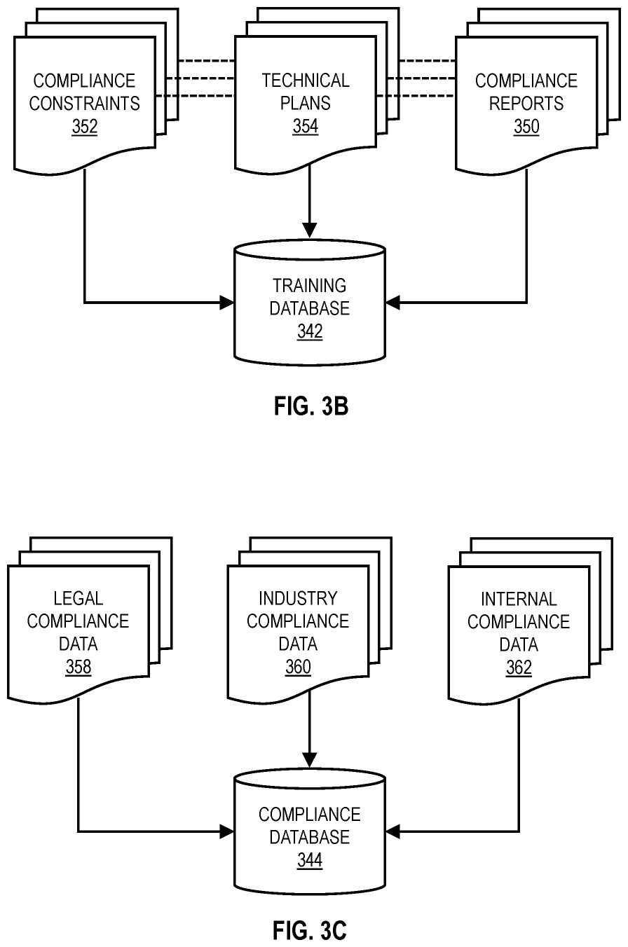

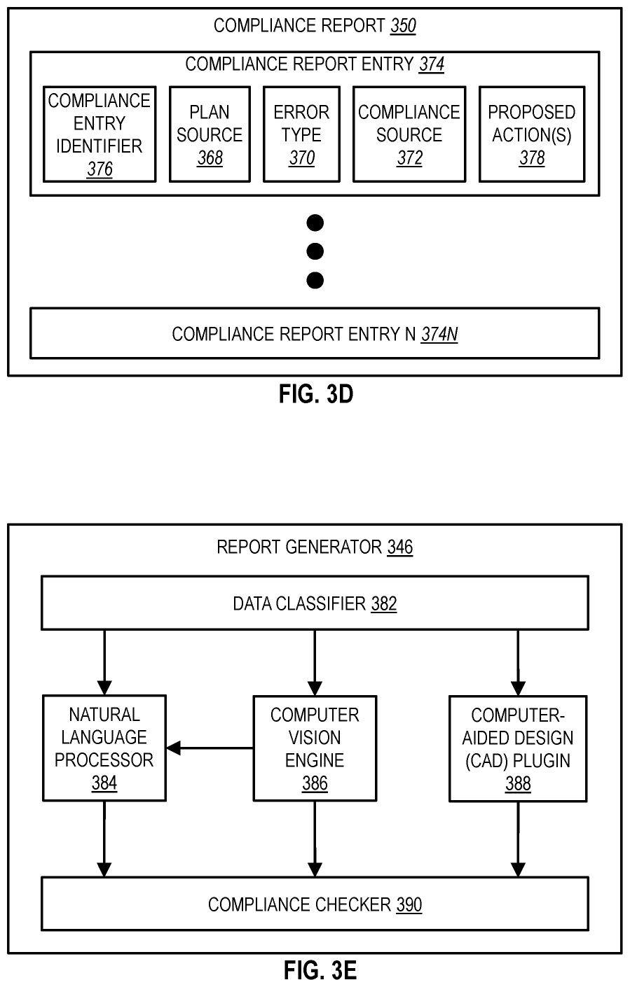

### FIG. 3A

FIG. 3A is a diagram of a computing system with a report generator and various components used by the report generator.

Training database 342 is a database (e.g., database 240) storing compliance constraints 352, technical plans 354, and compliance reports 350. In one or more embodiments, training database 342 may be read, searched, queried, and/or otherwise accessed (to obtain any data therein) by software executing in computing environment 200 (e.g., report generator 346). Additional details regarding the data in training database 342 may be found in the description of FIG. 3B.

Compliance database 344 is a database (e.g., database 240) storing legal compliance data 358, industry compliance data 360, and internal compliance data 362. In one or more embodiments, compliance database 344 may be read, searched, queried, and/or otherwise accessed (to obtain any data therein) by a component of computing environment 200 (e.g., report generator 346). Additional details regarding the data in compliance database 344 may be found in the description of FIG. 3C.

Report generator 346 is software that processes technical plan 354 and compliance constraints 352 (as inputs) and generates compliance report 350 (as an output). In one or more embodiments, report generator 346 may be a large language model (LLM) in the form of an artificial neural network trained using one or more methods of machine learning and artificial intelligence. Additional details regarding report generator 346 may be found in the description of FIG. 3E.

Computer-aided design (CAD) application 348 is software that allows for the creation, display, and/or manipulation of digital models (i.e., stored as data). In one or more embodiments, technical plan 354 includes proposed designs for a well system in file formats that are readable by a CAD application 348 (e.g., CAD file formats). In turn, report generator 346 may operatively connect to a CAD application (e.g., via CAD plugin 388) to allow for the reading, review, and analysis of the CAD files of technical plan 354.

Compliance report 350 is a data structure that includes compliance report entries 374 that specify errors present in the associated technical plan 354 and proposed action(s) 378 to correct the identified errors. Additional details regarding compliance report 350 may be found in the description of FIG. 3D.

### FIG. 3B

FIG. 3B is a diagram of a training database and the data therein.

Compliance constraint 352 is data specifying which compliance data (i.e., legal compliance data 358, industry compliance data 360, and/or internal compliance data 362) is applicable to associated technical plan 354 (and/or portions of technical plan 354). Non-limiting examples of compliance constraints 352 include an alphanumeric string that uniquely references specific compliance data (e.g., “43 CFR § 3160”, “ISO 14693”) and/or a unique identifier that may be used to identify the text of the relevant compliance data (e.g., 921204.0828). Further, in one or more embodiments, compliance constraint may be associated with a specific document and/or portion of technical plan 354 (e.g., ISO 11960 (“casing and tubing for wells”) may be associated with the design documents of technical plan 354 related to proposed casing design).

Technical plan 354 is data that includes documents, drawings, and technical information for the proposed design of a well system. Non-limiting examples of data in technical plan 354 include design drawings, a design of service document, a list of materials used for construction, vendor data (e.g., name, country, applicable legal compliance data 358), a list of equipment/machinery used during construction/operation, documentation for all equipment/machinery (e.g., specifications, manuals, manufacturer, manufacture date/location, applicable industry compliance data 360), a list of personnel (e.g., names, employer, title, role, applicable legal compliance data 358), and/or any other documentation related to the design, construction, and operation of a well system. In one or more embodiments, compliance constraints 352 may be included partially or wholly within technical plan 354.

### FIG. 3C

FIG. 3C is a diagram of a compliance database and the data therein.

Legal compliance data 358 is data that includes government specified requirements (and/or guidance) related to a field of industry. Non-limiting examples of legal compliance data 358 include laws, statutes, acts, ordinances, regulations, codes, mandates, edicts, decrees, rulings, opinions, interpretations, and/or any other form of government provided guidance related to the associated field of industry. Non-limiting examples of fields of industry include engineering design, construction, accounting, law, medicine, and/or any good or service for which there may be government involvement. Further, a field of industry may be any subcategory of a broader field of industry (e.g., design of buildings, design of plumbing systems, design of fire suppressant (“sprinkler”) systems, etc.). As a specific non-limiting example, a field of industry may be ‘patent drawing requirements’ (a subcategory of patent drafting, patent law, and law generally), where the specific legal compliance data 358 may include, in part, the text of 35 United States Code (USC) § 113; 37 Code of Federal Regulations (CFR) §§ 1.81, 1.83, 1.84, 1.85; and Manual of Patent Examining Procedure (MPEP) §§ 608, 1825, 1606. In one or more embodiments, legal compliance data 358 may reference and mandate compliance with industry compliance data 360 (e.g., Texas' Local Government Code sec. 214.214 mandates compliance with the National Electrical Code (NEC)).

As used herein, legal compliance data 358 may relate to the design of well system(s) for extracting hydrocarbons (e.g., oil and gas). In such instances, legal compliance data 358 may include relevant international (e.g., treaty), national (e.g., federal), regional (e.g., state), and local (e.g., municipal) requirements (for any government in the world) related to the design of wells, construction of wells, method of extraction of hydrocarbons, and transportation of hydrocarbons. As a non-limiting example, in the United States, federal requirements may include the National Environmental Policy Act (NEPA) (42 U.S.C. § 4321 et seq.), the National Historic Preservation Act (NHPA) (16 U.S.C. §§ 470a-470w-6 et. seq.), the Endangered Species Act (6 USC § 1531-1544), regulations of the bureau of land management (BLM) under 43 CFR § 3160, and any related regulations (or guidance) (e.g., titles 30, 36, and 43 of the CFR, written opinions, court rulings, etc.). Further, state requirements may include, for example, title 3 (“Oil and Gas”) of Texas' Natural Resources Code and any regulations promulgated thereunder. One of ordinary skill in the art would appreciate the identification of applicable legal compliance data 358 based on the region(s) and/or jurisdiction(s) for a well design (e.g., a proposed well system in Ragusa, Italy would utilize legal compliance data 358 from the city of Ragusa (local), the province of Ragusa (regional), Italy (national), and the European Union (EU) (international)).

Industry compliance data 360 is data that includes publicly available documentation (e.g., industry standards, specifications, manuals, guidance, published best practices, procedures, etc.) related to the practice of the associated field of industry (e.g., those set by trade/standard-setting bodies, organizations, or associations). As a non-limiting example, for the field of industry of financial accounting, industry compliance data 360 may include the Generally Accepted Accounting Principles (GAAP) as published in the Accounting Standard Codification (ASC) by the Financial Accounting Standards Board (FASB). As another example, for the field of industry of construction and electrical systems, industry compliance data 360 may include the National Electrical Code (NEC) as published by the national Fire Protection Association (NFPA). Additionally, industry compliance data 360 may include published technical papers, patents, patent application publications,

As used herein, industry compliance data 360 may relate to the design of well system(s) for extracting hydrocarbons (e.g., oil and gas). In such instances, industry compliance data 360 may include any publication of the American Petroleum Institute (API), the American National Standards Institute (ANSI), the International Organization for Standardization (ISO) (e.g., ISO 10423 “Wellhead & tree equipment”, ISO 14693 “Drilling equipment”, etc.), the American Society for Testing and Materials (ASTM) (e.g., ASTM's “geotechnical engineering standards”, “petroleum standards”, etc.), and/or any other relevant organization.

Internal compliance data 362 is data that includes proprietary (e.g., nonpublic, trade secret, company-specific, internally developed, etc.) documentation (e.g., standards, specifications, manuals, guidance, procedures, etc.) related to the practice of the associated field of industry. As a non-limiting example, internal compliance data 362 may include flowcharts and detailed procedures for performing steps of a broader operation. As another non-limiting example, internal compliance data 362 may include specifications that comprehensively incorporate all relevant legal compliance data 358 and industry compliance data 360 for a given operation into a single reference. Further, internal compliance data 362 may further include heightened requirements that satisfy and exceed what is required by legal compliance data 358 and industry compliance data 360. Internal compliance data 362 may include documentation developed by one business organization and licensed (or purchased) by another business organization (e.g., manuals, support guides, and technical documents of licensed equipment and software). As used herein, internal compliance data 362 may relate to the design of well system(s) for extracting hydrocarbons (e.g., oil and gas). In such instances, internal compliance data 362 may include any documentation for the design, construction, and operation of a well system.

### FIG. 3D

FIG. 3D is a diagram of a compliance report. Compliance report 350 may include one or more compliance report entries 374 that is uniquely associated with a suspected error in an associated technical plan 354.

Compliance report entry 374 is a data structure within compliance report 350 that may include information (e.g., compliance entry identifier 376, plan source 368, error type 370, compliance source 372, proposed action 378) for a suspected error present in an associated technical plan 354. Non-limiting examples of compliance report entry 374 include a tuple in a database, a row in table (e.g., spreadsheet), and a line in a text file. In one or more embodiments, any one compliance report entry 374 may be uniquely identifiable by compliance entry identifier 376 stored therein.

Compliance entry identifier 376 is an identifier uniquely associated with the single compliance report entry 374 in which it is stored. Generally, an identifier is data that uniquely specifies some other data. Non-limiting examples of an identifier include a tag, an alphanumeric entry, a filename, and a row number in table. An alphanumeric expression may be encoded using a standard protocol for alphanumeric characters (e.g., Unicode, American Standard Code for Information Interchange (ASCII), etc.). In one or more embodiments, an identifier may be an integer count (e.g., 1, 2, 3, 4, 5, etc.) or index (e.g., 0, 1, 2, 3, etc.). One of ordinary skill in the art, having the benefit of this detailed description, would appreciate that an identifier may be any data that identifies an entry. In any embodiment, an identifier may be generated by one or more software components of the system and/or by a user of the system.

Plan source 368 is data that includes the location, content, and/or reference to an error in technical plan 354. In one or more embodiments, plan source 368 may specify the specific document (e.g., filename, unique identifier, etc.) and the location within that document (e.g., page number, paragraph number, line, figure number, etc.) within technical plan 354. In one or more embodiments, plan source 368 may include a copy of the content of technical plan 354 that includes the identified error (e.g., a string of text, a portion of a figure).

Error type 370 is data that relates to the type of error identified in the associated technical plan 354. Non-limiting examples of error type 370 include (i) “noncompliance” indicating a conflict between the content of a required compliance constraint 352 and an aspect of technical plan 354, (ii) “conflict” or “inconsistency” indicating conflicting design criteria within technical plan 354, (iii) “review” indicating noncompliance with a best-practice, or that additional action is required (e.g., take an allowable exception to a required standard).

Compliance source 372 is data that includes an identifier and/or content of the compliance data (any type in compliance database 344) that caused the identification of the error (e.g., “43 CFR § 3160”). In one or more embodiments, compliance source 372 may be a copy of the corresponding compliance constraint 352. In one or more embodiments, compliance source 372 may include a copy of the content of the associated compliance data (e.g., a string of text quoting the compliance data).

Proposed action 378 is data that specifies a proposed modification to technical plan 354 to correct the error specified in the same compliance report entry 374. In one or more embodiments, proposed action 378 is a string that provides a human-readable modification. As a non-limiting example, proposed action 378 may be the alphanumeric string “plunger pin material: SS316” where the “plunger pin material” specified technical plan 354 is “SS304”.

### FIG. 3E

FIG. 3E is a report generator and the components therein. Report generator 346 may include one or more software components (e.g., subprocesses, etc.) to perform one or more corresponding functions of report generator 346 more broadly. In one or more embodiments, any one or more of the software components shown in report generator 346 may be external software entities (e.g., called and executed by report generator 346)

Data classifier 382 is software that accepts assorted data (e.g., mixed file/data types) as an input, parses the assorted data into individual data chunks (e.g., files or file parts), classifies the individual data chunks, and provides the data chunk to the associated software entity for further processing.

Natural language processor 384 is software that may process natural language alphanumeric text (e.g., human readable word structures, sentences, paragraphs, etc.) as an input, “interpret” the provided text using a neural network, extract relevant data, and organize that relevant data for further analysis. As a non-limiting example, natural language processor 384 may generate a data structure (e.g., a table) that includes a list of identified properties (attributes and values) from the provided input (e.g., country: United States, target depth: 4,000 ft, etc.). Accordingly, the output data (“property”) may be more easily compared against the constraints of the project.

Computer vision engine 386 is software that may process and interpret visual information from image data provided as an input. In one or more embodiments, computer vision engine 386 may include algorithms and/or neural networks that are trained mimic a human ability to recognize and understand images and videos. Computer vision engine 386 may use deep learning models that may be trained on datasets of visual content (e.g., image data in training database 342), thereby allowing the computer vision engine 386 to identify patterns and features in the image data and extract relevant data for further analysis. As a non-limiting example, computer vision engine 386 may generate a data structure (e.g., a table) that includes a list of identified properties (attributes and values) from the provided input (e.g., drilling mud: 70% water, drill pipe material: 4145H modified steel, etc.). Accordingly, the output data (“property”) may be more easily compared against the constraints of the project.

Computer-aided design (CAD) plugin 388 is software that allows for communication with CAD application 348. In one or more embodiments, CAD plugin 388 is an application programming interface used to initiate the reading and processing of CAD files. In one or more embodiments, CAD plugin 388 may initiate the generation of data (by CAD application 348) that is independently readable by report generator 346 (e.g., list of materials for natural language processor 384, standard drawing for computer vision engine 386). In one or more embodiments, CAD plugin 388 may initiate analysis of CAD files (by CAD application 348) to identify errors (within CAD files) that necessitate that use of CAD application 348 (e.g., interference detection, tolerances, etc.). As a non-limiting example, CAD plugin 388 may generate a data structure (e.g., a table) that includes a list of identified properties (attributes and values) from the provided input (e.g., weight: 85 lbs, volume: 1.4 cubic ft, etc.). Accordingly, the output data (“property”) may be more easily compared against the constraints of the project.

Compliance checker 390 is software that compares the outputs of the three software components (natural language processor 384, computer vision engine 386, CAD plugin 388) to each other and to compliance data (data in compliance database 344) specified by compliance constraints 352. In turn, compliance checker 390 identifies errors (if any) where the analyzed technical plan 354 does not satisfy the text of the specified compliance constraints 352 and generates a compliance report based on those errors.

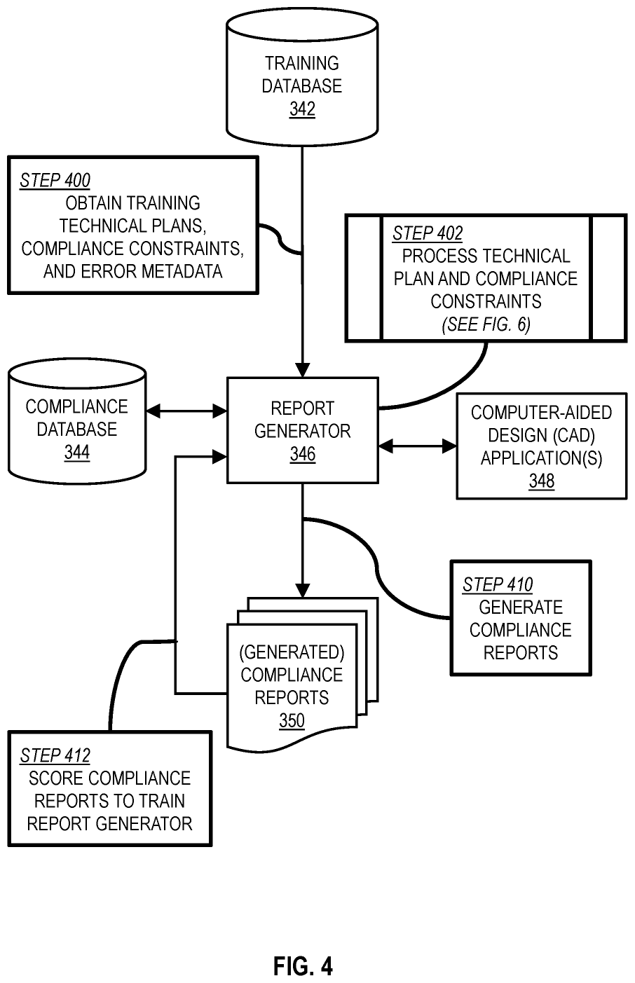

### FIG. 4

FIG. 4 is a flowchart of a method for training a report generator using a training database. All or a portion of the method shown may be performed by one or more components of information handling system 201 (see description in FIG. 2), report generator (see description in FIG. 3E), or a user thereof. While the various steps in this flowchart are presented and described sequentially, a person of ordinary skill in the relevant art (having the benefit of this detailed description) would appreciate that some or all steps may be executed in different orders, combined, or omitted, and some or all steps may be executed in parallel.

In step 400, report generator 346 obtains data from training database 342, including technical plans 354, associated compliance constraints 352, and associated compliance reports 350.

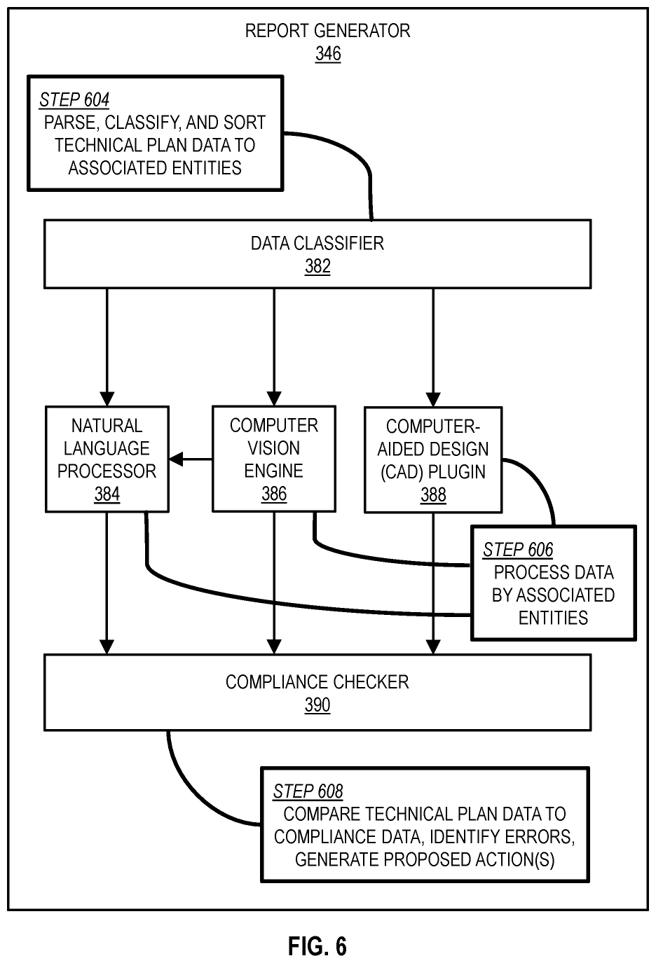

In step 402, report generator 346 processes the data from training database 342. Additional details regarding step 402 may be found in the description of FIG. 6 and the discussion of Steps 604-608.

In step 410, report generator 346 generates compliance report(s) 350 based on the processing of technical plans 354 and compliance constraints 352 from training database 342. In turn, report generator 346 may provide the generated compliance report(s) 350 to a user of the system (e.g., by storing compliance report(s) 350 in a location accessible by the user).

In step 412, the compliance report(s) 350 are scored. In one or more embodiments, compliance report(s) 350 are scored based on existence of common errors (e.g., compliance report entries 374) present in both the generated compliance report(s) 350 and the corresponding compliance reports 350 obtained from training database 342 (and associated with the analyzed technical plan 354 and compliance constraints 352). That is, if report generator 346 successfully produces a generated compliance report 350 that includes all of the errors (e.g., compliance report entries 374) in the pre-existing compliance report 350, a greater score is given to the generated compliance report 350 (comparatively to a generated compliance report 350 that did not successfully identify all of the known errors). One of ordinary skill in the art, provided the benefit of this detailed description, would understand that the score assigned to a generated compliance report 350 may correlate to the quantity and quality of identified errors (e.g., fewer errors and/or errors of lesser quality would result in a comparatively lower score a generated compliance report 350).

In one or more embodiments, a generated compliance report 350 that successfully identifies and includes valid errors (e.g., compliance report entries 374) that are not present in the existing compliance report 350 may be provided an even greater score. Further, in one or more embodiments, a higher score may be provided to a generated compliance report 350, if the generated compliance report 350 includes a proposed action 378 that would successfully ameliorate the identified error. Similarly, a lower score may be assigned to a generated compliance report 350 if proposed action(s) 378 thereof either (i) do not fix the identified error, and/or (ii) create other errors if implemented.

After one or more generated compliance report(s) 350 are scored, the scores are provided to report generator 346. In turn, upon obtaining the scores, report generator 346 tunes the neural network(s) (underlying the LLM) to better identify and analyze errors in technical plan 354. In one or more embodiments, an artificial intelligence (AI) model of an LLM is tuned based on scored feedback (e.g., scored generated compliance report(s) 350) by utilizing a process called supervised learning. Initially, the model is trained on a dataset with labeled examples. Then, feedback is gathered, often in the form of scores or evaluations, to assess the model's performance. Adjustments are made to the model's parameters and architecture based on this feedback to improve its accuracy and overall performance. This iterative process continues until the desired level of performance is achieved. In one or more embodiments, supervised learning modifies a neural network through a process that involves adjusting its weights and biases to minimize the difference between its predicted outputs (the generated compliance report(s) 350) and the actual target values provided in training database 342 (the existing compliance report(s) 350). This is typically achieved through backpropagation and gradient descent. Accordingly, in one or more embodiments, the process of FIG. 4 (steps 400, 402, 410, and 412) may be repeated until a satisfactory quality of compliance report 350 is generated.

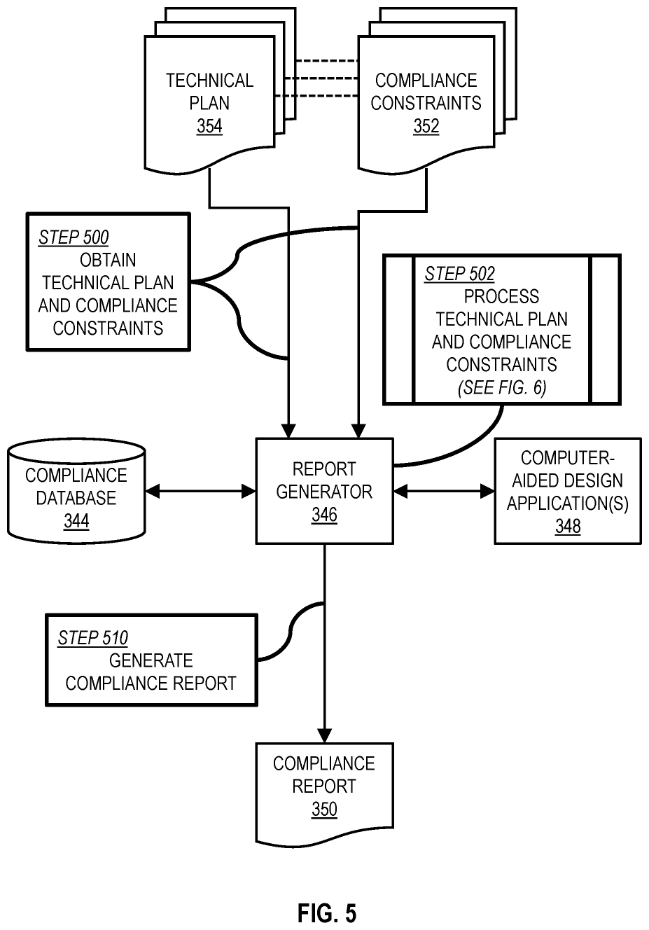

### FIG. 5

FIG. 5 is a flowchart of a method for using a report generator to generate a compliance report. All or a portion of the method shown may be performed by one or more components of information handling system 201 (see description in FIG. 2), report generator (see description in FIG. 3E), or a user thereof. While the various steps in this flowchart are presented and described sequentially, a person of ordinary skill in the relevant art (having the benefit of this detailed description) would appreciate that some or all steps may be executed in different orders, combined, or omitted, and some or all steps may be executed in parallel.

In step 500, report generator 346 obtains technical plans 354 and associated compliance constraints 352. In one or more embodiments, technical plans 354 and associated compliance constraints 352 may be provided by a user of the system (e.g., as an input) for analysis by report generator 346. In one or more embodiments, report generator 346 is utilizing a trained model (e.g., using the process of FIG. 4) before being supplied with technical plans 354 and associated compliance constraints 352 to generate compliance report 350 for “real-world” use.

In step 502, report generator 346 processes technical plans 354 and associated compliance constraints 352. Additional details regarding step 402 may be found in the description of FIG. 6 and the discussion of Steps 604-608.

In step 510, report generator 346 generates a compliance report 350 based on the processing of technical plans 354 and associated compliance constraints 352. In turn, report generator 346 may provide compliance report 350 to a user of the system (e.g., by storing compliance report 350 in a location accessible by the user).

### FIG. 6

FIG. 6 is a flowchart of a method of the internal components of a report generator when generating a compliance report. All or a portion of the method shown may be performed by one or more components of information handling system 201 (see description in FIG. 2), report generator (see description in FIG. 3E), or a user thereof. While the various steps in this flowchart are presented and described sequentially, a person of ordinary skill in the relevant art (having the benefit of this detailed description) would appreciate that some or all steps may be executed in different orders, combined, or omitted, and some or all steps may be executed in parallel.

Step 604, report generator 346 receives technical plans 354 and associated compliance constraints 352. In turn, report generator 346 uses data classifier 382 to parse, classify, sort, and disseminate the data chunks of technical plan 354 to the respective software entity.

In one or more embodiments, data classifier 382 may identify distinct separable file parts based on their organization (e.g., separate files as provided), chunks of extractable data within any one file (e.g., a document with alphanumeric text and an appendix of images), uncompressing compressed files (e.g., binary files, archive files, etc.) to parse multiple distinct data types therein.

In one or more embodiments, data classifier 382 may classify the data type based on metadata stored in the data (e.g., file type, headers, file extension, etc.), and/or known standards for data organization (e.g., recognized patterns of data that are associated with a type of data).

In one or more embodiments, data classifier 382 may classify data chunks into one of three different types (i) alphanumeric text, (ii) images, and (iii) CAD files. Based on the classification into these types, data classifier 382 then passes the data chunk (e.g., calls a function) to natural language processor 384, computer vision engine 386, or computer-aided design (CAD) plugin 388, respectively.

In step 606, report generator 346 uses natural language processor 384, computer vision engine 386, and/or CAD plugin 388 to process the data chunks provided to the respective software entities. In one or more embodiments, each of the software entities analyzes the data chunks to extract properties (attributes and values), which are more easily comparable to compliance data. As a non-limiting example, a CAD drawing may have the file name “casing_connection.dwg” and include a technical drawing pointing to the inner side of the object showing “ø=4.5 in”. Report generator 346 would send this file to the associated CAD application 348 and retrieve back a data structure including the individual string “ø=4.5 in”. From this, report generator 346 generates the attribute “casing connection inner diameter” and assigns the value “4.5 in”.

In one or more embodiments, computer vision engine 386 may be provided an image of alphanumeric text. In such instances, computer vision engine 386 is trained to identify that the document is of text (and not originally an image) perform optical character recognition (OCR) to make the document text-readable, and then pass the data to natural language processor 384 for analysis.

In step 608, report generator 346 compares the properties of technical plan 354 with the properties of compliance data to identify errors. For each identified error, a compliance report entry 374 is generated in compliance report 350.

In one or more embodiments, compliance checker 390 processes the identified compliance data to extract properties (attributes and values), which are more easily comparable to properties of technical plan 354. As a non-limiting example, compliance checker 390 identifies that compliance data includes a design constraint requiring casing inner diameters to be at least 5.5 in. Accordingly, the attribute “casing inner diameter” is assigned the value “≥5.5 in”. Thus, compliance checker 390 determines that the previously generated technical property (“casing connection inner diameter” with the value “4.5 in”) from technical plan 354 does not satisfy the compliance property (“casing inner diameter” with the value “≥5.5 in”).

Accordingly, report generator 346 generates a compliance report entry 374 that includes “casing_connection.dwg” (for plan source 368), “noncompliance” (for error type 370), the specified design constraint (for compliance source 372), and “increase casing connection to 5.5 in internal diameter” (as proposed action 378).

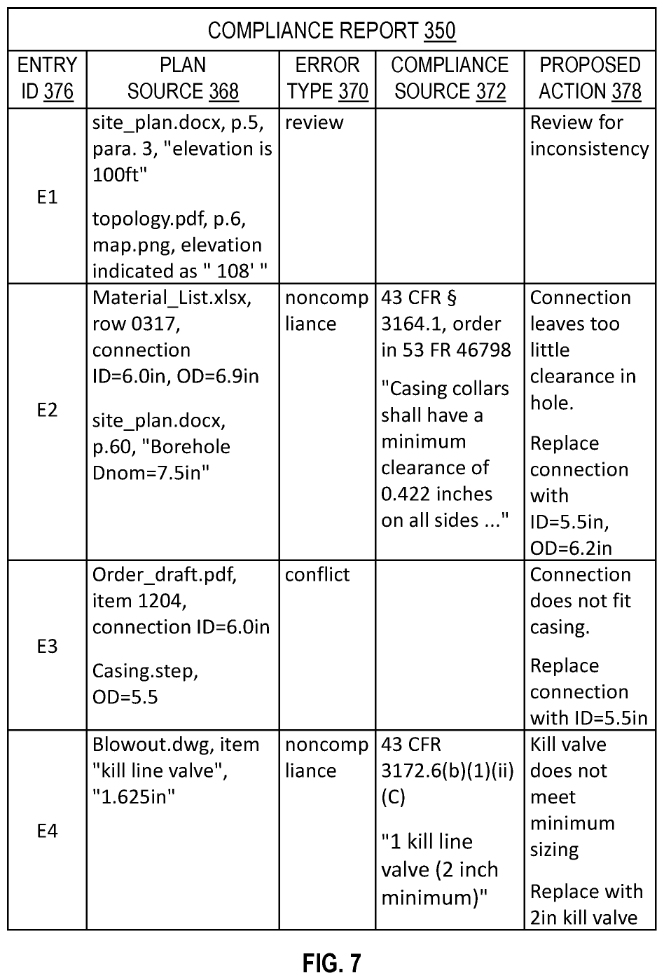

### FIG. 7

FIG. 7 is a table of an example compliance report.

As shown in the example of FIG. 7, compliance report 350 is shown with four compliance report entries 374 (the bottom four rows). Each compliance report entry 374 includes a unique compliance entry identifier 376 (shown as “entry ID 376”), plan source 368, error type 370, compliance source 372, and proposed action 378.

The first compliance report entry 374 has a compliance entry identifier 376 of “E1”. For this entry, report generator 346 identified that the document “site_plan.docx” (of technical plan 354) specifies that the elevation of the construction site is “100 ft”. Accordingly, attribute “site elevation” is generated and assigned the value “100 ft”. Further, report generator 346 identified that the document “topology.pdf” (of technical plan 354) includes an image with text indicating the elevation of the site is “108 ft”. Similarly, report generator 346 generated attribute “site elevation” and assigned the value “108 ft”. In turn, report generator 346 determines that an attribute (“site elevation”) is described having two different values (100 ft and 108 ft). However, as no known requirement is violated and no technical issues are identified, report generator assigns error type 370 “review”, does not provide compliance source 372, and generates proposed action 378 of “Review for inconsistency”.

The second compliance report entry 374 has a compliance entry identifier 376 of “E2”. For this entry, report generator 346 identified that row “0317” of the worksheet “Material_List.xlsx” (of technical plan 354) lists the part “connection” with an inner diameter (ID) of “6.0 in” and having an outer diameter (OD) of “6.7 in”. Further, report generator 346 identified that “site_plan.docx” (of technical plan 354) lists “borehole” as having a nominal diameter (Dnom) of “7.5 in”. In turn, report generator 346 identifies that the minimum clearance around the connection, in the borehole, would 0.4 in (half of the difference between the borehole's nominal diameter and the OD of the connection).

Accordingly, four technical properties are generated, (i) attribute “casing inner diameter” with the value “6.0 in”, (ii) attribute “casing outer diameter” with the value “6.7 in”, (iii) attribute “borehole nominal diameter” with the value “7.5 in”, and (iv) attribute “casing clearance” with the value “0.4 in”.

Next, report generator 346 identifies that compliance constraints 352 list “43 CFR § 3160 et seq.” as required regulations that must be met. Further, 43 CFR § 3164.1 refers to an order, published in the federal register (FR), at 53 FR 46798 requiring that “Casing collars shall have a minimum clearance of 0.422 inches on all sides . . . ”. In turn, report generator 346 generates a compliance property with attribute “casing clearance minimum” and a value of “0.422 in”. As a result, report generator 346 generates error type 370 as “noncompliance”, provides the reference to the regulation and the relevant portion of the order in compliance source 372, and generates proposed action 378 that reads, in part, “Replace connection with ID=5.5 in, OD=6.2 in” which would leave a minimum clearance of 0.65 in and therefore satisfy the identified applicable regulation (43 CFR § 3164.1).

The third compliance report entry 374 has a compliance entry identifier 376 of “E3”. For this entry, report generator 346 identified that the document “Order_draft.pdf” (of technical plan 354) lists “item 1204” as “connection” as having an ID of 6.0 in. Further, report generator 346 identified that in CAD file “Casing.step” (of technical plan 354), the OD of the casing is listed as 5.5 in. Report generator 346 identifies that the selected connections would not fit onto selected casing (6.0 in vs 5.5 in). In turn, report generator 346 generates error type 370 of “conflict”, does not generate compliance source 372, and generates proposed action 378 stating, in part, “Replace connection with ID=5.5 in” (a connection that is compatible with the chosen casing). Further, proposed action 378 for the third compliance entry 374 also satisfies the error of the second compliance entry 374, allowing both errors to be solved (e.g., not generating a proposed action 378 that will cause an error elsewhere, or is incompatible with another proposed action 378).

The fourth compliance report entry 374 has a compliance entry identifier 376 of “E3”. For this entry, report generator 346 identified that the document “Blowout.dwg” (of technical plan 354) includes a drawing for “kill line valve”, showing a size of “1.625 in”. Report generator 346 further identifies that compliance constraints 352 list “43 CFR § 3170 et seq.” as required regulations that must be met. In turn, report generator 346 analyzes the relevant regulations and identifies that 43 CFR § 3172.6(b)(1)(ii)(C) requires “1 kill line valve (2 inch minimum)”, where “2 inch minimum” is interpreted to mean any satisfactory “kill line valve” must be at least 2 in. As a result, report generator 346 generates error type 370 as “noncompliance”, provides the reference to the regulation and the relevant portion of the order in compliance source 372, and generates proposed action 378 that reads, in part, “[k]ill valve does not meet minimum sizing. Replace with 2 in kill valve” which would then satisfy the applicable identified regulation (43 CFR § 3172.6(b)(1)(ii)(C)).

### Solutions and Improvements

The methods and systems described above are an improvement over the current technology as the methods and systems described herein provide a large language model (LLM) trained to generate a “compliance report” that may (i) identify errors in a technical plan, and (ii) provide proposed corrective actions to those errors. Further, during the training and utilization of the LLM, the LLM may access a compliance database that specifies all of the potentially relevant legal and technical constraints, including those applicable to the technical plan. Thus, when “reviewing” the document, the LLM may consider all constraints—as a single entity—and propose a solution that simultaneously satisfies all of the specified compliance constraints.

Accordingly, time, effort, and costs caused by conventional methods are reduced. Specifically, the effort and time spent iteratively correcting errors of a technical plan are offloaded to software to more quickly propose (potentially) multiple solutions. Further, smaller errors that may go unnoticed by a human reviewer may be identified by the LLM and corrected earlier, allowing for smoother implementation of the technical plan.

### Statements

The systems and methods may comprise any of the various features disclosed herein, comprising one or more of the following statements.

Statement 1. A method for generating a compliance report, comprising receiving, by a report generator, a technical plan and a compliance constraint; processing the technical plan and the compliance constraint; generating the compliance report based on the processing; and providing the compliance report to a user.

Statement 2. The method of statement 1, wherein processing the technical plan comprises comparing the technical plan to compliance data; and identifying an error in the technical plan.

Statement 3. The method of statement 2, wherein the compliance report comprises: a plan source, of the technical plan, associated with the error; and a compliance source, of the compliance data, associated with the error.

Statement 4. The method of statements 2-3, wherein the compliance constraint specifies the compliance data.

Statement 5. The method of statements 1-4, wherein after providing the compliance report to the user, the method further comprises: receiving a score associated with the compliance report; and updating a large language model based on the score.

Statement 6. The method of statements 1-5, wherein processing the technical plan comprises: parsing the technical plan into a plurality of data chunks; and disseminating each of the plurality of data chunks to one selected from the group consisting of: a natural language processor; a computer vision engine; and a computer-aided design plugin.

Statement 7. The method of statements 1-6, wherein a data chunk, of the plurality of data chunks, is provided to the natural language processor, and wherein the natural language processor extracts a property from the data chunk.

Statement 8. The method of statement 7, wherein the method further comprises: identifying compliance data associated with the property based on the compliance constraint; obtaining the compliance data from a compliance database; and comparing the property to the compliance data.

Statement 9. The method of statement 8, wherein after comparing the property to the compliance data, the method further comprises: making a determination that the property does not satisfy the compliance data.

Statement 10. The method of statement 9, wherein after making the determination, the method further comprises: generating a compliance report entry, in the compliance report, wherein the compliance report entry comprises: the property; and the compliance data.

Statement 11. The method of statement 10, wherein the compliance report entry further comprises: a proposed action, wherein the proposed action specifies a modification of the property.

Statement 12. The method of statement 11, wherein the compliance report entry further comprises: a second proposed action, wherein the second proposed action specifies a second modification of the property.

Statement 13. The method of statements 6-12, wherein a data chunk, of the plurality of data chunks, is provided to the computer vision engine, and wherein the computer vision engine extracts a property from the data chunk.

Statement 14. The method of statements 6-13, wherein a data chunk, of the plurality of data chunks, is provided to the computer-aided design plugin, and wherein the computer-aided design plugin extracts a property from the data chunk.

Statement 15. A system, comprising memory storing instructions; a processor, wherein the processor is configured to execute the instructions, and wherein when the processor executes the instructions, the processor performs a method for generating a compliance report, comprising: receiving a technical plan and a compliance constraint; processing the technical plan and the compliance constraint; generating the compliance report based on the processing; and providing the compliance report to a user.

Statement 16. The system of statement 15, wherein processing the technical plan comprises: parsing the technical plan into a plurality of data chunks; and disseminating each of the plurality of data chunks to one selected from the group consisting of: a natural language processor; a computer vision engine; and a computer-aided design plugin.

Statement 17. The system of statement 16, wherein a data chunk, of the plurality of data chunks, is provided to the natural language processor, and wherein the natural language processor extracts a property from the data chunk.

Statement 18. The system of statement 17, wherein the method further comprises: identifying compliance data associated with the property based on the compliance constraint; obtaining the compliance data from a compliance database; and comparing the property to the compliance data.

Statement 19. The system of statement 18, wherein after comparing the property to the compliance data, the method further comprises: making a determination that the property does not satisfy the compliance data.

Statement 20. The system of statement 19, wherein after making the determination, the method further comprises: generating a compliance report entry, in the compliance report, wherein the compliance report entry comprises: the property; and the compliance data.

### General Notes

As it is impracticable to disclose every conceivable embodiment of the technology described herein, the figures, examples, and description provided herein disclose only a limited number of potential embodiments. A person of ordinary skill in the relevant art would appreciate that any number of potential variations or modifications may be made to the explicitly disclosed embodiments, and that such alternative embodiments remain within the scope of the broader technology. Accordingly, the scope should be limited only by the attached claims. Further, the compositions and methods are described in terms of “comprising,” “containing,” or “including” various components or steps, the compositions and methods may also “consist essentially of” or “consist of” the various components and steps. Moreover, the indefinite articles “a” or “an,” as used in the claims, are defined herein to mean one or more than one of the elements that it introduces. Certain technical details, known to those of ordinary skill in the relevant art, may be omitted for brevity and to avoid cluttering the description of the novel aspects.

For further brevity, descriptions of similarly named components may be omitted if a description of that similarly named component exists elsewhere in the application. Accordingly, any component described with respect to a specific figure may be equivalent to one or more similarly named components shown or described in any other figure, and each component incorporates the description of every similarly named component provided in the application (unless explicitly noted otherwise). A description of any component is to be interpreted as an optional embodiment-which may be implemented in addition to, in conjunction with, or in place of an embodiment of a similarly-named component described for any other figure.

### Lexicographical Notes

As used herein, adjective ordinal numbers (e.g., first, second, third, etc.) are used to distinguish between elements and do not create any ordering of the elements. As an example, a “first element” is distinct from a “second element”, but the “first element” may come after (or before) the “second element” in an ordering of elements. Accordingly, an order of elements exists only if ordered terminology is expressly provided (e.g., “before”, “between”, “after”, etc.) or a type of “order” is expressly provided (e.g., “chronological”, “alphabetical”, “by size”, etc.). Further, use of ordinal numbers does not preclude the existence of other elements. As an example, a “table with a first leg and a second leg” is any table with two or more legs (e.g., two legs, five legs, thirteen legs, etc.). A maximum quantity of elements exists only if express language is used to limit the upper bound (e.g., “two or fewer”, “exactly five”, “nine to twenty”, etc.). Similarly, singular use of an ordinal number does not imply the existence of another element. As an example, a “first threshold” may be the only threshold and therefore does not necessitate the existence of a “second threshold”.

As used herein, the word “data” may be used as an “uncountable” singular noun—not as the plural form of the singular noun “datum”. Accordingly, throughout the application, “data” is generally paired with a singular verb (e.g., “the data is modified”). However, “data” is not redefined to mean a single bit of digital information. Rather, as used herein, “data” means any one or more bit(s) of digital information that are grouped together (physically or logically). Further, “data” may be used as a plural noun if context provides the existence of multiple “data” (e.g., “the two data are combined”).

As used herein, the term “operative connection” (or “operatively connected”) means the direct or indirect connection between devices that allows for the transmission of data. For example, the phrase ‘operatively connected’ may refer to a direct connection (e.g., a direct wired or wireless connection between devices) or an indirect connection (e.g., multiple wired and/or wireless connections between any number of other devices connecting the operatively connected devices).

As used herein, indefinite articles “a” and “an” mean “one or more”. That is, the explicit recitation of “an” element does not preclude the existence of a second element, a third element, etc. Further, definite articles (e.g., “the”, “said”) mean “any one of” (the “one or more” elements) when referring to previously introduced element(s). As an example, there may exist “a processor”, where such a recitation does not preclude the existence of any number of other processors. Further, “the processor receives data, and the processor processes data” means “any one of the one or more processors receives data” and “any one of the one or more processors processes data”. It is not required that the same processor both (i) receive data and (ii) process data. Rather, each of the steps (“receive” and “process”) may be performed by different processors.

What is claimed is:

1. A method for generating a compliance report, comprising:
receiving, by a report generator, a technical plan and a compliance constraint;
processing the technical plan and the compliance constraint;
generating the compliance report based on the processing; and
providing the compliance report to a user.

2. The method of claim 1, wherein processing the technical plan comprises:
comparing the technical plan to compliance data; and
identifying an error in the technical plan.

3. The method of claim 2, wherein the compliance report comprises:
a plan source, of the technical plan, associated with the error; and
a compliance source, of the compliance data, associated with the error.

4. The method of claim 2, wherein the compliance constraint specifies the compliance data.

5. The method of claim 1, wherein after providing the compliance report to the user, the method further comprises:
receiving a score associated with the compliance report; and
updating a large language model based on the score.

6. The method of claim 1, wherein processing the technical plan comprises:
parsing the technical plan into a plurality of data chunks; and
disseminating each of the plurality of data chunks to one selected from the group consisting of:
a natural language processor;
a computer vision engine; and
a computer-aided design plugin.

7. The method of claim 6, wherein a data chunk, of the plurality of data chunks, is provided to the natural language processor, and wherein the natural language processor extracts a property from the data chunk.

8. The method of claim 7, wherein the method further comprises:
identifying compliance data associated with the property based on the compliance constraint;
obtaining the compliance data from a compliance database; and
comparing the property to the compliance data.

9. The method of claim 8, wherein after comparing the property to the compliance data, the method further comprises:
making a determination that the property does not satisfy the compliance data.

10. The method of claim 9, wherein after making the determination, the method further comprises:
generating a compliance report entry, in the compliance report, wherein the compliance report entry comprises:
the property; and
the compliance data.

11. The method of claim 10, wherein the compliance report entry further comprises:
a proposed action, wherein the proposed action specifies a modification of the property.

12. The method of claim 11, wherein the compliance report entry further comprises:
a second proposed action, wherein the second proposed action specifies a second modification of the property.

13. The method of claim 6, wherein a data chunk, of the plurality of data chunks, is provided to the computer vision engine, and wherein the computer vision engine extracts a property from the data chunk.

14. The method of claim 6, wherein a data chunk, of the plurality of data chunks, is provided to the computer-aided design plugin, and wherein the computer-aided design plugin extracts a property from the data chunk.

15. A system, comprising:
memory storing instructions;
a processor, wherein the processor is configured to execute the instructions to perform
a method for generating a compliance report, comprising:
receiving a technical plan and a compliance constraint;
processing the technical plan and the compliance constraint;
generating the compliance report based on the processing; and
providing the compliance report to a user.

16. The system of claim 15, wherein processing the technical plan comprises:
parsing the technical plan into a plurality of data chunks; and
disseminating each of the plurality of data chunks to one selected from the group consisting of:
a natural language processor;
a computer vision engine; and
a computer-aided design plugin.

17. The system of claim 16, wherein a data chunk, of the plurality of data chunks, is provided to the natural language processor, and wherein the natural language processor extracts a property from the data chunk.

18. The system of claim 17, wherein the method further comprises:
identifying compliance data associated with the property based on the compliance constraint;
obtaining the compliance data from a compliance database; and
comparing the property to the compliance data.

19. The system of claim 18, wherein after comparing the property to the compliance data, the method further comprises:
making a determination that the property does not satisfy the compliance data.

20. The system of claim 19, wherein after making the determination, the method further comprises:
generating a compliance report entry, in the compliance report, wherein the compliance report entry comprises:
the property; and
the compliance data.
